(19) United States
(12) Patent Application Publication
(10) Pub. No.: US 2019/0196244 A1
(43) Pub. Date: Jun. 27, 2019

(54) ELECTRO-OPTICAL DEVICE, ELECTRONIC DEVICE, AND PROJECTION-TYPE DISPLAY DEVICE

(71) Applicant: SEIKO EPSON CORPORATION, Tokyo (JP)

(72) Inventors: Jun HIRAI, Azumino-shi (JP); Toru AOKI, Shiojiri-shi (JP); Shuko YANAGISAWA, Chino-shi (JP); Shinta ENAMI, Matsumoto-shi (JP)

(73) Assignee: SEIKO EPSON CORPORATION, Tokyo (JP)

(21) Appl. No.: 16/229,891

(22) Filed: Dec. 21, 2018

(30) Foreign Application Priority Data
Dec. 25, 2017 (JP) 2017-247351

(51) Int. Cl. G02F 1/1345; H05K 1/18; H05K 1/11; G03B 21/00; G03B 33/12

(52) U.S. Cl. CPC G02F 1/13452; H05K 1/189; H05K 2201/10136; G03B 21/006; G03B 33/12; H05K 1/117

(57) ABSTRACT

An electro-optical device includes two substrates (a first substrate and a second substrate) respectively having ends overlapped with each other and coupled to an electro-optical panel. Other ends of the two substrates respectively serve as a first terminal region and a second terminal region. The second substrate includes a third extended portion extending linearly to overlap with a first extended portion of the first substrate in a thickness direction, and a fourth extended portion extending to a position different from a position of a second extended portion of the first substrate to allow the first terminal region and the second terminal region to be away from each other in a direction intersecting with an extending direction of the third extended portion and to not overlap with each other in the thickness direction.

### BACKGROUND

### 1. Technical Field

The invention relates to an electro-optical device, an electronic device, and a projection-type display device. The electro-optical device is equipped with an electro-optical panel coupled with a substrate.

### 2. Related Art

Some electro-optical devices, such as liquid crystal display devices and organic electro-luminescence devices, are adopted with a structure where ends of a plurality of flexible substrates are overlapped with each other and coupled to an electro-optical panel (see JP-A-2010-102219). In the electro-optical device described in JP-A-2010-102219, two substrates identical to each other in shape and size wholly overlap with each other to extend.

In the electro-optical device described in JP-A-2010-102219, the two substrates respectively include other ends respectively provided with terminal regions. The terminal regions of the two substrates are respectively coupled to a wiring substrate. In this state, such a configuration where two substrates wholly overlap with each other, as the electro-optical device described in JP-A-2010-102219, faces difficulty in commonly coupling other ends (terminal regions) of the two substrates to a wiring substrate. In addition, with the configuration where the two substrates wholly overlap with each other, as the electro-optical device described in JP-A-2010-102219, when coupling the other ends (terminal regions) of the two substrates respectively to wiring substrates different from each other, and when coupling the other end (terminal region) of one of the substrates to one of the wiring substrates, the other one of the substrates becomes an obstruction, requiring greater time and effort for the coupling operation.

### SUMMARY

An advantage of some aspects of the invention is to provide an electro-optical device, an electronic device, and a projection-type display device. The electro-optical device is capable of efficiently coupling, to a wiring substrate, other ends of a plurality of substrates respectively having ends overlapped with each other and coupled to an electro-optical panel.

For the issue described above, an electro-optical device according to an aspect of the invention includes an electro-optical panel, a first substrate having flexibility and including a first end coupled to the electro-optical panel and a second end disposed opposite to the first end and provided with a first terminal region arranged with a plurality of terminals, and a second substrate having flexibility and including a third end coupled to the electro-optical panel and a fourth end disposed opposite to the third end and provided with a second terminal region arranged with a plurality of terminals. When the first substrate and the second substrate are developed on a same plane, the first terminal region and the second terminal region are located at positions different from each other on the plane and do not overlap with each other in the thickness direction.

In the invention, the first substrate and the second substrate overlapping with each other in the thickness direction are coupled to the electro-optical panel. Therefore, the first substrate and the second substrate can be arranged within a narrower space around the electro-optical panel. Even in this case, the first terminal region and the second terminal region are located at positions different from each other in an in-plane direction of the first substrate and the second substrate, and do not overlap with each other in the thickness direction. Therefore, after the other end (terminal region) of one of the substrates is coupled to the wiring substrate, when coupling the other end (terminal region) of the other one of the substrates to the wiring substrate, the one of the substrates does not become an obstruction, achieving an efficient coupling operation.

In the invention, such an aspect can be adopted that, when the first substrate and the second substrate are developed on the same plane, the first substrate includes a first extended portion extending from the first end to a position toward the second end, a first terminal region forming portion including the second end and formed with the first terminal region, and a second extended portion extending from the first extended portion to the first terminal region forming portion, and the second substrate includes a third extended portion extending from the third end to a position toward the fourth end to overlap with the first extended portion in the thickness direction, a second terminal region forming portion including the fourth end and formed with the second terminal region, and a fourth extended portion bending in a direction intersecting with an extending direction of the third extended portion and extending from the third extended portion to the second terminal region forming portion to allow the first terminal region forming portion and the second terminal region forming portion to be away from each other in a direction intersecting with the extending direction of the third extended portion without being overlapped with each other in the thickness direction. According to the aspect, since the second extended portion of the first substrate and the fourth extended portion of the second substrate respectively extend in directions different from each other, the first terminal region forming portion does not overlap with the second substrate in the thickness direction, while the second terminal region forming portion does not overlap with the first substrate in the thickness direction. Therefore, after the other end (terminal region) of one of the substrates is coupled to the wiring substrate, when coupling the other end (terminal region) of the other one of the substrates to the wiring substrate, the one of the substrates does not become an obstruction, achieving an efficient coupling operation.

In the invention, such an aspect can be adopted that, when the first substrate and the second substrate are developed on the same plane, the first extended portion and the second extended portion extend in a same direction. According to the aspect, since the first substrate extends in a certain direction, and only the second substrate bends, the first substrate and the second substrate can be arranged within a narrower space. According to the aspect, such an aspect can be adopted that, when the first substrate and the second substrate are developed on the single plane, the first terminal region and the second terminal region each extend in a direction intersecting with an extending direction of the first extended portion.

In the invention, such an aspect can be adopted that, when the first substrate and the second substrate are developed on the same plane, the first substrate includes a first extended portion extending to an intermediate position from the first end toward the second end, a first terminal region forming portion including the second end and formed with the first terminal region, and a second extended portion extending from the first extended portion to the first terminal region forming portion, and the second substrate includes a third extended portion extending to an intermediate position from the third end toward the fourth end to overlap with the first extended portion in the thickness direction, a second terminal region forming portion including the fourth end and formed with the second terminal region, and a fourth extended portion extending from the third extended portion to the second terminal region forming portion to overlap with the second extended portion in the thickness direction. According to the aspect, the first terminal region forming portion also does not overlap with the second substrate in the thickness direction, while the second terminal region forming portion also does not overlap with the first substrate in the thickness direction. Therefore, after the other end (terminal region) of one of the substrates is coupled to the wiring substrate, when coupling the other end (terminal region) of the other one of the substrates to the wiring substrate, the one of the substrates does not become an obstruction, achieving an efficient coupling operation. Since the first extended portion and the third extended portion overlap with each other, as well as the second extended portion and the fourth extended portion overlap with each other, the first substrate and the second substrate can be arranged within a narrower space. According to the aspect, such an aspect can be adopted that the first terminal region and the second terminal region respectively extend in the extending direction of the first extended portion.

In the invention, such an aspect can be adopted that the first substrate and the second substrate extend in the same direction to lengths different from each other. Even in this case, the first terminal region and the second terminal region are located at positions different from each other in the in-plane direction of the first substrate and the second substrate, and the first terminal region and the second terminal region do not overlap with each other in the thickness direction. Therefore, after the other end (terminal region) of one of the substrates is coupled to the wiring substrate, when coupling the other end (terminal region) of the other one of the substrates to the wiring substrate, the one of the substrates does not become an obstruction, achieving an efficient coupling operation. Since the first substrate and the second substrate overlap with each other in a wider area, the first substrate and the second substrate can be arranged within a narrower space.

In the invention, such an aspect can be adopted that the first extended portion and the third extended portion each are mounted with a driving integrated circuit (IC).

In the invention, such an aspect can be adopted that the first substrate includes a third substrate mounted with the driving IC on a flexible substrate extending from an end coupled to the electro-optical panel, and a fourth substrate having flexibility, coupled to the other end of the third substrate, and provided with the first terminal region, and the second substrate includes a fifth substrate mounted with the driving IC on a flexible substrate extending from an end coupled to the electro-optical panel, and a sixth substrate having flexibility, coupled to the other end of the fifth substrate, and provided with the second terminal region. According to the aspect, expensive chip-on-film (COF) substrates (the third substrate and the fifth substrate) can be only partially used for the first substrate and the second substrate, while cost-effective extension substrates (the fourth substrate and the sixth substrate) can be used for the first substrate and the second substrate to achieve appropriate lengths.

In the invention, such an aspect can be adopted that the third substrate and the fifth substrate are identical in shape and length. According to the aspect, the expensive COF substrates with identical specifications can be used for the first substrate and the second substrate, achieving a cost reduction.

In an electronic device equipped with an electro-optical device applied with the invention, such an aspect can be adopted that, in a state where the first substrate and the second substrate respectively bend in a direction identical to the thickness direction at intermediate positions in the extending direction, the first terminal region and the second terminal region are coupled to a wiring substrate. In this case, such an aspect can be adopted that the first terminal region and the second terminal region are coupled in common to the wiring substrate. According to the aspect, the first substrate and the second substrate can share the wiring substrate, achieving a cost reduction.

In a projection-type display device, equipped with a plurality of electro-optical devices applied with the invention, such an aspect can be adopted that includes a light source unit configured to emit light source light to be incident to each of the plurality of electro-optical devices, a cross dichroic prism configured to synthesize light modulated by each of the plurality of electro-optical devices, and a projection optical system configured to project imaging light emitted from an emission surface of the cross dichroic prism. The plurality of electro-optical devices include a first electro-optical device facing a first incident surface facing the emission surface of the cross dichroic prism, a second electro-optical device facing a second incident surface lying between the emission surface and the first incident surface of the cross dichroic prism, and a third electro-optical device facing a third incident surface facing the second incident surface of the cross dichroic prism. In each of the first electro-optical device, the second electro-optical device, and the third electro-optical device, in a state where the first substrate and the second substrate each bend in the thickness direction toward an opposite side to the cross dichroic prism at intermediate positions in the extending direction, the first terminal region and the second terminal region are coupled to a wiring substrate. In this case, such an aspect can be adopted that the first terminal region and the second terminal region are coupled in common to the wiring substrate. According to the aspect, the first substrate and the second substrate can share the wiring substrate, achieving a cost reduction.

In a projection-type display device, equipped with a plurality of electro-optical devices applied with the invention, such an aspect can be adopted that includes a light source unit configured to emit light source light to be incident to each of the plurality of electro-optical devices, a cross dichroic prism configured to synthesize light modulated by the plurality of electro-optical devices, and a projection optical system configured to project imaging light emitted from an emission surface of the cross dichroic prism. The plurality of electro-optical devices include a first electro-optical device facing a first incident surface facing the emission surface of the cross dichroic prism, a second electro-optical device facing a second incident surface lying between the emission surface and the first incident surface of the cross dichroic prism, and a third electro-optical device facing a third incident surface facing the second incident surface of the cross dichroic prism. In each of the first electro-optical device, the second electro-optical device, and the third electro-optical device, in a state where the first substrate and the second substrate each bend in the thickness direction toward an opposite side to the cross dichroic prism at intermediate positions in the extending direction, the first terminal region and the second terminal region are coupled to a wiring substrate. In each of the second electro-optical device and the third electro-optical device, the fourth extended portion bends in a direction to be away from the projection optical system.

In a projection-type display device according to the invention, such an aspect can be adopted that, in each of the second electro-optical device and the third electro-optical device, the first extended portion, the second extended portion, the third extended portion, and the fourth extended portion do not protrude from a virtual surface including the emission surface toward the projection optical system. According to the aspect, a space for arranging actuators, for example, each configured to perform focusing-driving in a projection optical system, and a movable region for the projection optical system, for example, can be secured around the virtual surface.

### BRIEF DESCRIPTION OF THE DRAWINGS

The invention will be described with reference to the accompanying drawings, wherein like numbers reference like elements.

FIG. 1 is an explanatory view illustrating an aspect of a planar configuration of a main part of a projection-type display device representing an example of an electronic device applied with the invention.

FIG. 2 is an explanatory view of the main part illustrated in FIG. 1 when viewed from a side.

FIG. 3 is an explanatory view of an optical unit used in the projection-type display device illustrated in FIG. 1.

FIG. 4 is an explanatory view illustrating a detailed configuration of the optical unit illustrated in FIG. 1.

FIG. 5 is an explanatory view schematically illustrating an aspect of the electro-optical device according to Exemplary Embodiment 1 of the invention when viewed diagonally.

FIG. 6 is an exploded perspective view of the electro-optical device illustrated in FIG. 5 with an electro-optical panel and a holder removed from each other.

FIG. 7 is an explanatory view schematically illustrating a planar configuration of the electro-optical device illustrated in FIG. 5.

FIG. 8 is an explanatory view illustrating a cross-sectional configuration of the electro-optical device illustrated in FIG. 5.

FIG. 9 is a perspective view schematically illustrating the electro-optical devices illustrated in FIG. 7 and other drawings, arranged around a cross dichroic prism.

FIG. 10 is a plan view schematically illustrating the electro-optical devices illustrated in FIG. 7 and other drawings, arranged around the cross dichroic prism.

FIG. 11 is an explanatory view schematically illustrating a planar configuration of an electro-optical device according to Exemplary Embodiment 2 of the invention.

FIG. 12 is an explanatory view schematically illustrating the electro-optical devices illustrated in FIG. 11 arranged around a cross dichroic prism.

FIG. 13 is an explanatory view schematically illustrating a planar configuration of an electro-optical device according to Exemplary Embodiment 3 of the invention.

FIG. 14 is an explanatory view schematically illustrating the electro-optical devices illustrated in FIG. 13 arranged around a cross dichroic prism.

FIG. 15 is an explanatory view schematically illustrating electro-optical devices arranged around a cross dichroic prism in a projection-type display device (electronic device), according to Exemplary Embodiment 4 of the invention.

FIG. 16 is an exploded perspective view of an electro-optical device according to Exemplary Embodiment 5 of the invention.

FIG. 17 is an explanatory view illustrating a cross-sectional configuration of the electro-optical device illustrated in FIG. 16.

### DESCRIPTION OF EXEMPLARY EMBODIMENTS

Exemplary embodiments of the invention will now be described herein with reference to the accompanying drawings. Note that, in each of the drawings to be referenced in the descriptions below, to make members and the like recognizable in terms of size in the drawings, the members and the like are illustrated in different scales, and a number of terminals and other like components is reduced. For an electronic device (projection-type display device), a rectangular coordinate system based on a, b, and c axes is used to represent directions. For an electro-optical device, a rectangular coordinate system based on x, y, and z axes is used to represent directions.

### Exemplary Embodiment 1

### Configuration of Projection-Type Display Device (Electronic Device)

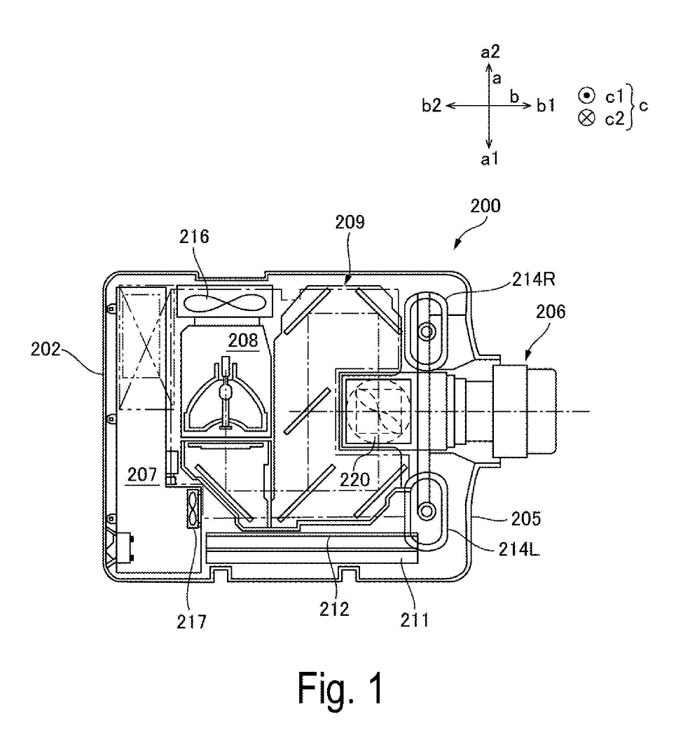

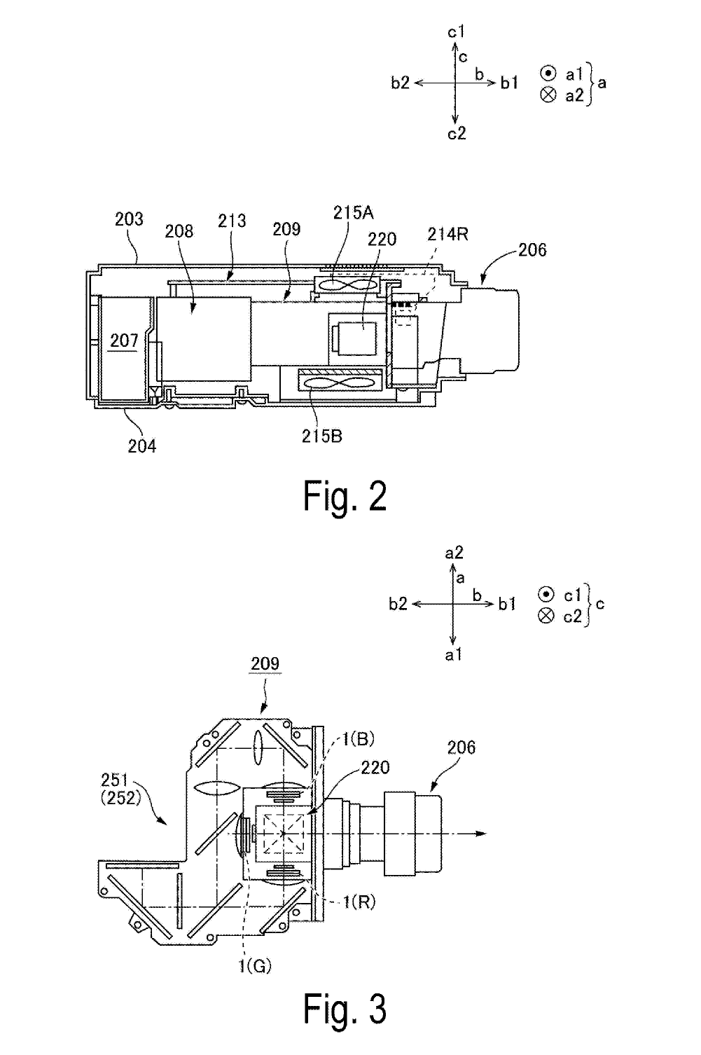

FIG. 1 is an explanatory view illustrating an aspect of a planar configuration of a main part of a projection-type display device representing an example of an electronic device applied with the invention. FIG. 2 is an explanatory view of the main part illustrated in FIG. 1 when viewed from a side. FIG. 3 is an explanatory view of an optical unit used in the projection-type display device illustrated in FIG. 1. On a rear end side of a projection-type display device 200 illustrated in FIGS. 1 and 2, outer packaging cases 202 and 205 are internally arranged with a power supply unit 207, as well as arranged with a light source unit 208 and an optical unit 209 lying adjacent to each other on a device front side, i.e., in front of the power supply unit 207 (on a side b1 in a b axis direction). Inside the outer packaging case 202, a base end side of a projection optical system 206 lies at a center of the device front side and in front of the optical unit 209. On a side al in an a axis direction, the optical unit 209 is arranged, in a device front-rear direction (the b axis direction), with an interface board 211 mounted with an input and output interface circuit. A video board 212 mounted with a video signal processing circuit is further arranged in parallel to the interface board 211. Above the optical unit 209 including the light source unit 208 (on a side cl in a c axis direction), a control board 213 for device driving control is arranged. At respective left and right corners on a device front end side, speakers 214R and 214L are arranged.

Above and below the optical unit 209, intake fans 215A and 215B for device internal cooling are arranged. On a device side surface, i.e., behind the light source unit 208, an exhaust fan 216 is arranged. Further, at a position facing ends of the interface board 211 and the video board 212, an auxiliary cooling fan 217 configured to introduce cooling air from the intake fan 215A into the power supply unit 207 is arranged. Among the fans, the intake fan 215B functions as a cooling fan (cooling device) for an electro-optical panel 100 described later.

In FIG. 3, optical elements configuring the optical unit 209 are supported by an upper light guide 251 or a lower light guide 252 made of metal, such as Mg or Al, including a cross dichroic prism 220 configuring colored light synthesizing means. The upper light guide 251 and the lower light guide 252 are respectively secured to an upper case 203 and a lower case 204 with screws.

Detailed Configuration of Optical Unit 209

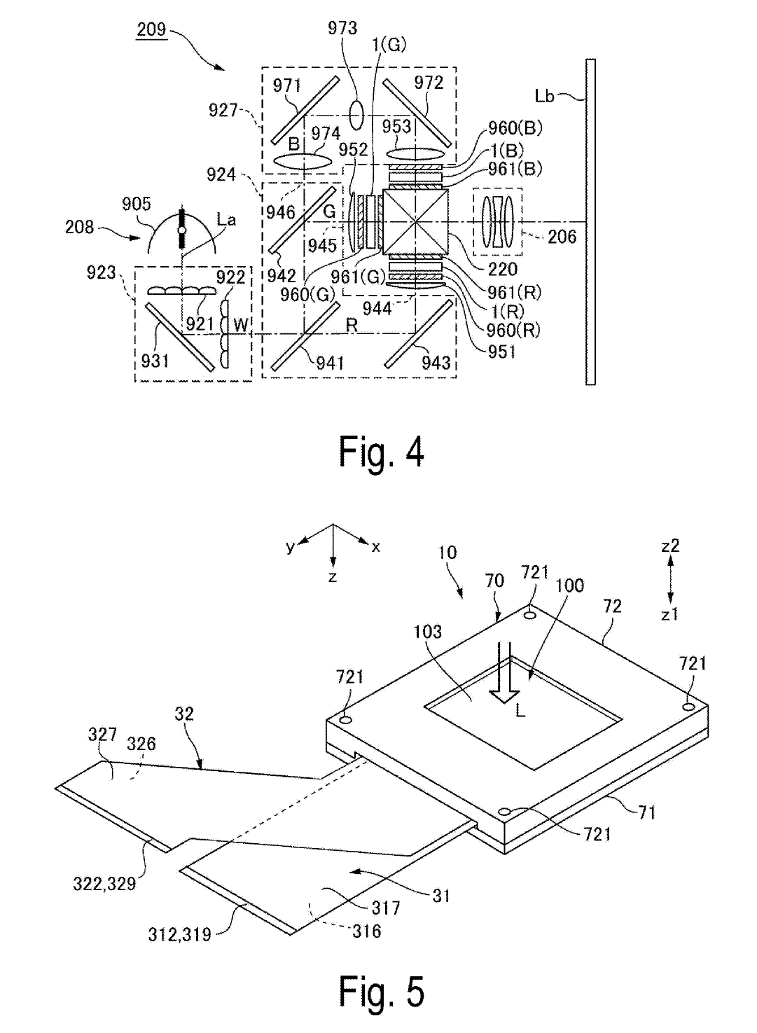

FIG. 4 is an explanatory view illustrating a detailed configuration of the optical unit 209 illustrated in FIG. 1. As illustrated in FIG. 4, the optical unit 209 includes a light source lamp 905 (the light source unit 208), an illumination optical system 923 including integrator lenses 921 and 922 serving as uniform illumination optical elements, a colored light separation optical system 924 configured to separate a light flux W to be emitted from the illumination optical system 923 into light fluxes R, G, and B respectively of red, green, and blue. The optical unit 209 further includes three transmission-type electro-optical devices 1(R), 1(G), and 1(B) serving as electro-optical panels (light valves) configured to modulate the colored light fluxes, the cross dichroic prism 220 serving as a colored light synthesizing optical system configured to synthesize the modulated colored light fluxes, and the projection optical system 206 configured to magnification-project the synthesized light flux onto a projection surface. A relay optical system 927 configured to guide the blue colored light flux B among the colored light fluxes separated by the colored light separation optical system 924 to the corresponding electro-optical device 1(B) is further included. The illumination optical system 923 includes a reflecting mirror 931 to bend at a right angle an optical axis La of light emitted from the light source lamp 905 in a device front direction. The integrator lenses 921 and 922 are arranged to pinch the reflecting mirror 931 to be orthogonal to each other in the front-rear direction.

The colored light separation optical system 924 includes a blue-green reflecting dichroic mirror 941, a green reflecting dichroic mirror 942, and a reflecting mirror 943. First, with the blue-green reflecting dichroic mirror 941, the blue colored light flux B and the green colored light flux G included in the light flux W and passed through the illumination optical system 923 are reflected at right angles to head toward the green reflecting dichroic mirror 942. The red colored light flux R passes through the blue-green reflecting dichroic mirror 941, is reflected at a right angle with the reflecting mirror 943 lying behind the blue-green reflecting dichroic mirror 941, and emits from an emitter 944 for red colored light flux to the colored light synthesizing optical system. Next, with the green reflecting dichroic mirror 942, among the blue and green light fluxes B and G reflected with the blue-green reflecting dichroic mirror 941, only the green colored light flux G is reflected at a right angle, and emits from an emitter 945 for green colored light flux to the colored light synthesizing optical system. The blue colored light flux B that passed through the green reflecting dichroic mirror 942 emits from an emitter 946 for blue colored light flux to the relay optical system 927. In the exemplary embodiment, set distances from an emitter for light fluxes of the illumination optical system 923 to the emitters 944, 945, and 946 for colored light fluxes in the colored light separation optical system 924 are all almost identical to each other.

Adjacent to emission-sides of the emitters 944 and 945 for red colored light flux and green colored light flux in the colored light separation optical system 924, condensing lenses 951 and 952 are respectively arranged. Therefore, a red colored light flux and a green colored light flux respectively emitted from the emitters are to be incident to the condensing lenses 951 and 952, and are thus paralleled. The paralleled red and green light fluxes R and G are respectively aligned in polarizing directions by polarizing plates 960(R) and 960(G), and are to be incident to the electro-optical devices 1(R) and 1(G), then, are modulated and are added with image information corresponding to the kinds of the colored light. That is, the electro-optical devices 1(R) and 1(G) are switching-controlled by driving means (not illustrated) with image signals corresponding to the image information, accordingly the colored light as thus passed is modulated. For the driving means described above, known means can be used as is.

On the other hand, the blue colored light flux B passes through the relay optical system 927, is further aligned by a polarizing plate 960(B) in a polarizing direction, guided to the corresponding electro-optical device 1(B), and, in here, similarly modulated in accordance with the image information. The relay optical system 927 includes a condensing lens 974, an incident-side reflecting mirror 971, an emission-side reflecting mirror 972, an intermediate lens 973 arranged between the mirrors described above, and a condensing lens 953 arranged in front of the electro-optical device 1(B). Among lengths of optical paths of the colored light fluxes, i.e., distances from the light source lamp 905 to respective liquid crystal panels, the length of the blue colored light flux B is greatest. Therefore, in the blue colored light flux B, a loss in light quantity becomes maximum. However, by providing the relay optical system 927, a loss in light quantity can be suppressed.

The colored light fluxes passing through the electro-optical devices 1(R), 1(G), and 1(B) and thus modulated are to be incident to polarizing plates 961(R), 961(G), and 961(B). Light passed through the polarizing plates 961(R), 961(G), and 961(B) is to be incident to the cross dichroic prism 220, and thus is synthesized. Imaging light synthesized in here passes through the projection optical system 206 including a plurality of lens systems, and is magnification-projected onto a projection-target surface Lb, such as a screen, lying at a predetermined position.

Configuration of Electro-Optical Device 1

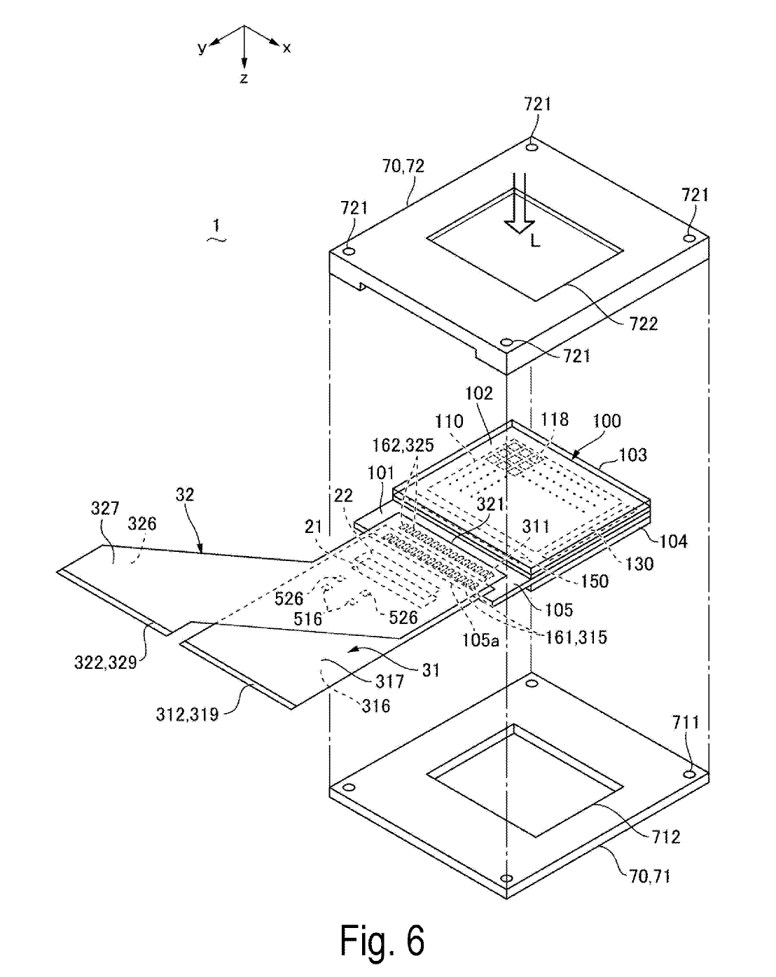

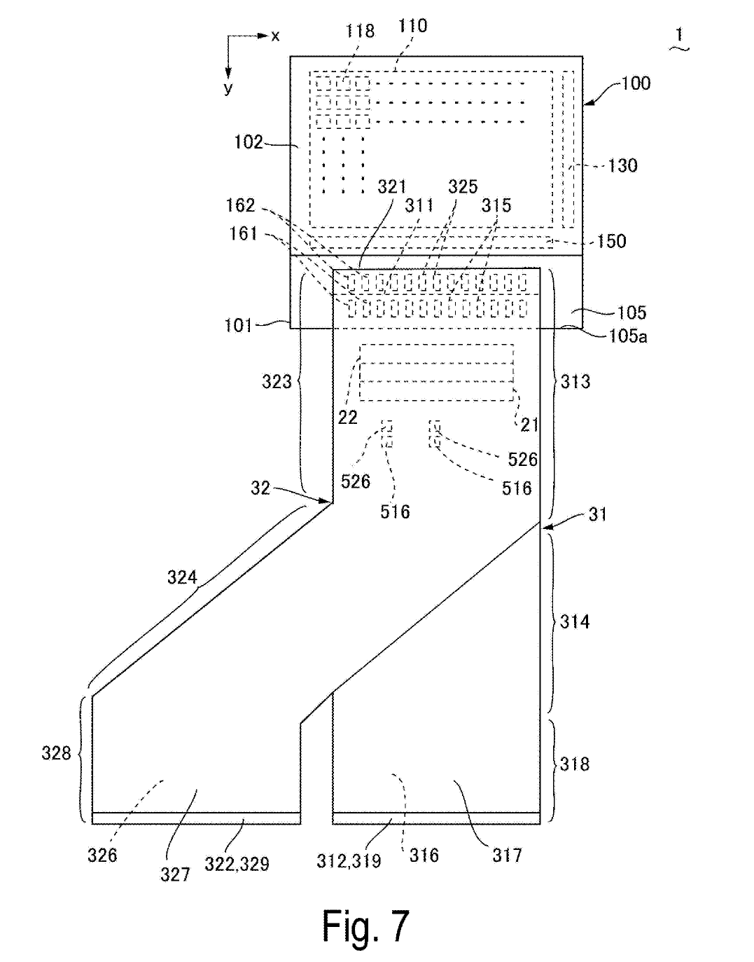

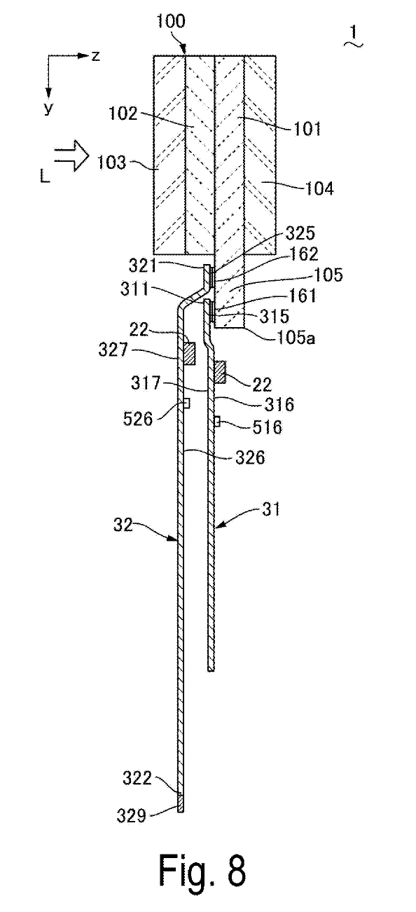

A configuration of each of the electro-optical devices 1 will be described herein with reference to FIGS. 5 to 8. FIG. 5 is an explanatory view schematically illustrating an aspect of the electro-optical device 1 according to Exemplary Embodiment 1 of the invention when viewed diagonally. FIG. 6 is an exploded perspective view of the electro-optical device 1 illustrated in FIG. 5, with the electro-optical panel 100 and a holder 70 removed from each other. FIG. 7 is an explanatory view schematically illustrating a planar configuration of the electro-optical device 1 illustrated in FIG. 5. FIG. 8 is an explanatory view illustrating a cross-sectional configuration of the electro-optical device 1 illustrated in FIG. 5, schematically illustrating the electro-optical device 1 being cut along the electro-optical panel 100 and a second substrate 32. Basic configurations of the electro-optical devices 1(R), 1(G), and 1(B) illustrated in FIG. 4 are identical to each other. Therefore, when configurations shared among the electro-optical devices 1(R), 1(G), and 1(B) are described, (R), (G), and (B) respectively indicative of the corresponding colors are not used, but simply referred to as the electro-optical device 1. FIGS. 5 to 8 each illustrate a first substrate 31 and the second substrate 32 developed on the same.

In FIGS. 5, 6, 7, and 8, the electro-optical device 1 includes the electro-optical panel 100, a plurality of substrates (the first substrate 31 and the second substrate 32) coupled to a side of the electro-optical panel 100, and the holder 70 configured to support the electro-optical panel 100 from both of sides in a thickness direction (a z axis direction). The electro-optical device 1 is a liquid crystal device configuring a light valve, for example, described with reference to FIG. 4 and other drawings. The electro-optical device 1 includes a liquid crystal panel serving as the electro-optical panel 100.

In the electro-optical panel 100, a counter substrate 102 formed with a common electrode (not illustrated), for example, is bonded to an element substrate 101 formed with pixel electrodes 118, for example, with a sealant (not illustrated). In the electro-optical panel 100, a region surrounded by the sealant is provided with a liquid crystal layer (not illustrated). The electro-optical panel 100 according to the exemplary embodiment is a transmission type liquid crystal panel. Therefore, the element substrate 101 and the counter substrate 102 are each made of a transmissive substrate, such as heat-resisting glass or a quartz substrate.

In the electro-optical panel 100, a region arranged with the pixel electrodes 118 in an x axis direction and a y axis direction represents a pixel region 110. In the electro-optical panel 100, a region overlapping with the pixel region 110 represents a display region. The element substrate 101 has a protrusion 105 protruded from the counter substrate 102 in the y axis direction. Along an edge (side 105a) of the protrusion 105, a plurality of terminals including first terminals 161 for image signal entry are arranged at predetermined pitches. Between the first terminals 161 and the pixel region 110 on the protrusion 105, a plurality of terminals including second terminals 162 for image signal entry are arranged at predetermined pitches. Therefore, the first terminals 161 and the second terminals 162 are away from each other in the y axis direction, and arranged along an edge of the element substrate 101. In FIGS. 6 and 7, the first terminals 161 and the second terminals 162 are arranged at positions identical to each other in the x axis direction. However, the first terminals 161 and the second terminals 162 may be away from each other each at a ½ pitch in the x axis direction.

In the electro-optical panel 100, light source light L (see FIG. 5 and other drawings) entering from the counter substrate 102, being modulated, and emitted from the element substrate 101 emits as display light. The electro-optical panel 100 has dust-proof glass laminated and arranged on at least one of a surface, opposite to the element substrate 101, of the counter substrate 102 and a surface, opposite to the counter substrate 102, of the element substrate 101. In the exemplary embodiment, the electro-optical panel 100 has first dust-proof glass 103 laminated and arranged, via an adhesive, for example, on the surface, opposite to the element substrate 101, of the counter substrate 102, and second dust-proof glass 104 laminated, arranged, and bonded, via an adhesive, for example, to the surface, opposite to the counter substrate 102, of the element substrate 101.

The holder 70 includes a first holder member 71 made of metal and configured to support the electro-optical panel 100 from a side z1 in the thickness direction (the z axis direction), and a second holder member 72 made of metal and configured to support the electro-optical panel 100 from another side z2 in the thickness direction. The first holder member 71 and the second holder member 72 are coupled together through such a method as bolts (not illustrated) that are screwed into holes 711 and 721 respectively formed in the first holder member 71 and the second holder member 72, for example. The first holder member 71 and the second holder member 72 are respectively formed with openings 712 and 722 allowing light source light and display light to pass through at positions overlapped with the display region (the pixel region 110) of the electro-optical panel 100. The holder 70 may be in an aspect having a heat sink (not illustrated) protruding toward a side in the y axis direction and partially overlapping with the first substrate 31 and the second substrate 32, to be described later.

In the electro-optical device 1, the electro-optical panel 100 is coupled with a plurality of substrates. In the exemplary embodiment, the electro-optical panel 100 is coupled with two substrates (the first substrate 31 and the second substrate 32). Specifically, the electro-optical device 1 includes the first substrate 31 having flexibility and including an end representing a first end 311 coupled to the element substrate 101 of the electro-optical panel 100, and the second substrate 32 overlapped with the first substrate 31 in the thickness direction, and having flexibility, and moreover including an end representing a third end 321 coupled to the element substrate 101 of the electro-optical panel 100. The first substrate 31 and the second substrate 32 extend from the electro-optical panel 100 in the y axis direction. The first substrate 31 has a surface 316 and another surface 317. The surface 316 lying opposite to the second substrate 32 is formed with a plurality of first output electrodes 315 on the first end 311 overlapping with the element substrate 101. The plurality of first output electrodes 315 are respectively coupled to the first terminals 161. The second substrate 32 has a surface 326 and another surface 327. The surface 326 facing the first substrate 31 is formed with a plurality of second output electrodes 325 on the third end 321 overlapping with the element substrate 101. The plurality of second output electrodes 325 are respectively coupled to the second terminals 162. The first substrate 31 has a second end 312 representing another end opposite to the first end 311. The second end 312 is provided with a first terminal region 319 arranged with a plurality of terminals (not illustrated). The second substrate 32 has a fourth end 322 representing another end opposite to the third end 321. The fourth end 322 is provided with a second terminal region 329 arranged with a plurality of terminals (not illustrated). The first terminal region 319 and the second terminal region 329 are to respectively electrically be coupled with a higher control circuit, for example, via a wiring substrate described later.

In the exemplary embodiment, as described below, when the first substrate 31 and the second substrate 32 are developed on the same plane (on an x-y plane), the first terminal region 319 and the second terminal region 329 are located at positions different from each other on the plane described above, and do not overlap with each other in the thickness direction. When attached to a product, the first substrate 31 and the second substrate 32 are respectively folded. Therefore, the term “developed on a single plane” means that the folded substrates are stretched on a plane.

More specifically, as illustrated in FIG. 7, the first substrate 31 includes a first extended portion 313 linearly extending in the y axis direction to an intermediate position from the first end 311 toward the second end 312, a first terminal region forming portion 318 including the second end 312 and formed with the first terminal region 319, and a second extended portion 314 linearly extending in the y axis direction from the first extended portion 313 to the first terminal region forming portion 318. In the first terminal region forming portion 318, the second end 312 (the first terminal region 319) of the first substrate 31 extends in the x axis direction orthogonal to an extending direction of the first extended portion 313 and the second extended portion 314.

The second substrate 32 includes a third extended portion 323 extending in the y axis direction to an intermediate position from the third end 321 toward the fourth end 322 to overlap with the first extended portion 313 in the thickness direction (the z axis direction), a second terminal region forming portion 328 including the fourth end 322 and formed with the second terminal region 329, and a fourth extended portion 324 extending from the third extended portion 323 to the second terminal region forming portion 328. So as not to allow the first terminal region forming portion 318 and the second terminal region forming portion 328 to be away from each other in a direction intersecting with the extending direction of the third extended portion 314, and overlap with each other in the thickness direction, the fourth extended portion 324 bends diagonally in a direction intersecting with the extending direction of the third extended portion 323 to extend from the third extended portion 323 to the second terminal region forming portion 328. In the second terminal region forming portion 328, the fourth end 322 (the second terminal region 329) extends in the x axis direction orthogonal to the extending direction of the first extended portion 313 and the third extended portion 323 to a position away in the x axis direction orthogonal to the extending direction of the first extended portion 313 and the third extended portion 323 from the second end 312 (the first terminal region 319) of the first substrate 31.

On the surface 316 of the first substrate 31, the first extended portion 313 is mounted with electronic components 516, such as a first driving IC 21 and a capacitor. An image signal, for example, is thus to be output from the first driving IC 21, via the first substrate 31, to the electro-optical panel 100. On the surface 326 of the second substrate 32, the third extended portion 323 is mounted with electronic components 526, such as a second driving IC 22 and a capacitor. An image signal, for example, is thus to be output from the second driving IC 22, via the second substrate 32, to the electro-optical panel 100.

As described above, in the electro-optical device 1 according to the exemplary embodiment, the first extended portion 313 of the first substrate 31 and the third extended portion 323 of the second substrate 32 overlapping with each other linearly extend. Therefore, the first substrate 31 and the second substrate 32 can be arranged within a narrower space around the electro-optical panel 100. Even in this case, the second extended portion 314 of the first substrate 31 and the fourth extended portion 324 of the second substrate 32 separated away from each other in the x axis direction extend. Therefore, the first terminal region 319 (the first terminal region forming portion 318) and the second terminal region 329 (the second terminal region forming portion 328) separated away from each other in an in-plane direction of the first substrate 31 and the second substrate 32 do not overlap with each other in the thickness direction. Therefore, the first terminal region 319 of the first substrate 31 and the second terminal region 329 of the second substrate 32 can be coupled in common to a wiring substrate, achieving an efficient coupling operation. That is, after one of the first substrate 31 and the second substrate 32 is coupled in common to the wiring substrate secured beforehand to a frame of an electronic device, for example, when coupling the other one of the substrates, the one of the substrates does not become an obstruction, allowing the substrates to be efficiently coupled. When coupling the first terminal region 319 and the second terminal region 329 of the second substrate 32 respectively to separate wiring substrates, after one of the first substrate 31 and the second substrate 32 is coupled to one of the wiring substrates, when coupling the other one of the substrates, the one of the substrates does not become an obstruction, allowing the substrates to be efficiently coupled.

Example of Mounting Electro-Optical Device 1 onto Projection-Type Display Device 200

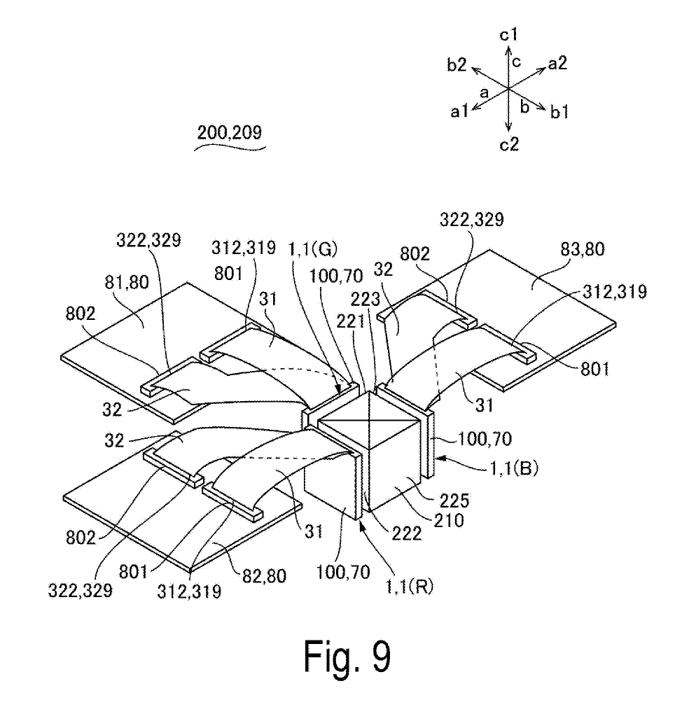

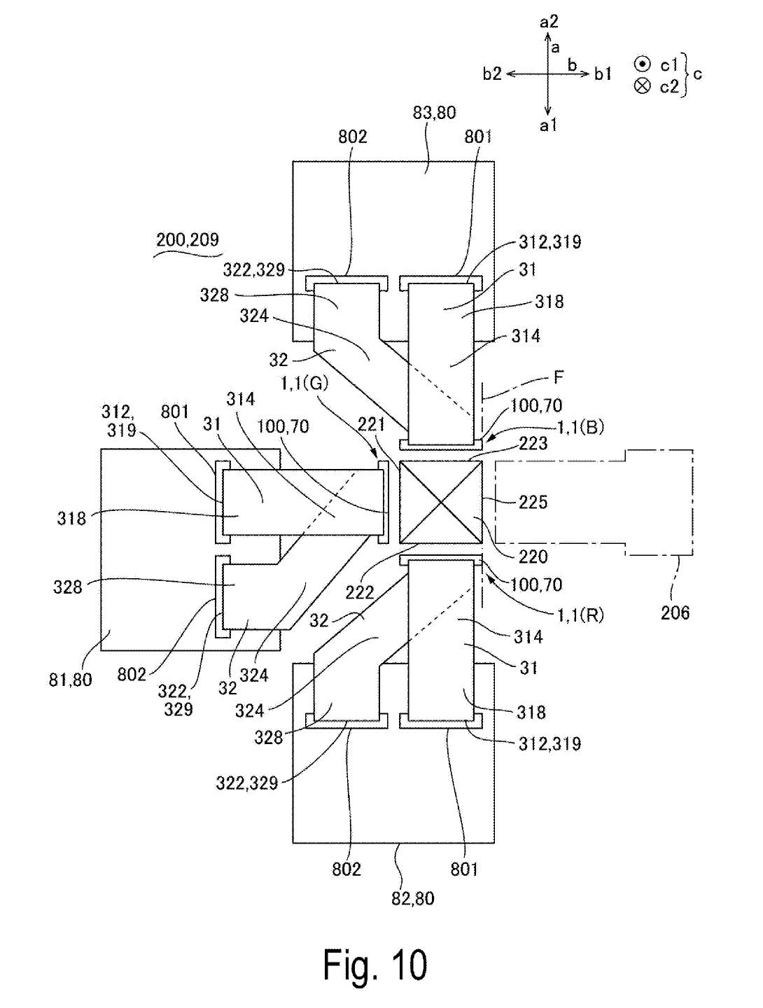

FIG. 9 is a perspective view schematically illustrating the electro-optical devices 1 illustrated in FIG. 7 and other drawings, arranged around the cross dichroic prism 220. FIG. 10 is a plan view schematically illustrating the electro-optical devices 1 illustrated in FIG. 7 and other drawings, arranged around the cross dichroic prism 220.

As illustrated in FIGS. 9 and 10, in the exemplary embodiment, when mounting each of the electro-optical devices 1(R), 1(G), and 1(B) onto the projection-type display device 200 (electronic device), while the first substrate 31 and the second substrate 32 respectively bend in a direction identical to the thickness direction at intermediate positions in the extending direction, the first terminal region 319 and the second terminal region 329 are coupled in common to a wiring substrate 80 (a first wiring substrate 81, a second wiring substrate 82, and a third wiring substrate 83).

In the exemplary embodiment, the plurality of electro-optical devices 1 are arranged around the cross dichroic prism 220. More specifically, the electro-optical device 1(G) serving as a first electro-optical device is arranged to face a first incident surface 221 facing an emission surface 225 of the cross dichroic prism 220. The electro-optical device 1(R) serving as a second electro-optical device is arranged to face a second incident surface 222 lying between the emission surface 225 and the first incident surface 221 of the cross dichroic prism 220. The electro-optical device 1(B) serving as a third electro-optical device is arranged to face a third incident surface 223 facing the second incident surface 222 of the cross dichroic prism 220.

In each of the three electro-optical devices 1(R), 1(G), and 1(B), the first substrate 31 and the second substrate 32 are respectively arranged to bend in the thickness direction toward an opposite side to the cross dichroic prism 220 at intermediate positions in the extending direction. In this state, the first terminal region 319 and the second terminal region 329 are coupled in common to the wiring substrate 80 (the first wiring substrate 81, the second wiring substrate 82, and the third wiring substrate 83) arranged in parallel to incident light emitted to each of the electro-optical devices 1(R), 1(G), and 1(B). Therefore, in each of the electro-optical devices 1(R), 1(G), and 1(B), without hindered by tip sides of the first substrate 31 and the second substrate 32 and the wiring substrate 80, an optical path of incident light to each of the electro-optical devices 1(R), 1(G), and 1(B) can be secured.

In the exemplary embodiment, the first terminal region 319 and the second terminal region 329 respectively serve as plugs for a board-to-board connector, for example. Therefore, the first wiring substrate 81, the second wiring substrate 82, and the third wiring substrate 83 are each formed with a socket 801 of the board-to-board connector to be inserted with the first terminal region 319, and a socket 802 of the board-to-board connector to be inserted with the second terminal region 329. In the exemplary embodiment, in the wiring substrate 80, the sockets 801 and 802 are arranged adjacent to each other in an extending direction of the sockets 801 and 802. Therefore, the first terminal region 319 and the second terminal region 329 can be respectively easily inserted into the sockets 801 and 802. In each of the three electro-optical devices 1(R), 1(G), and 1(B), the first terminal region 319 of the first substrate 31 and the second terminal region 329 of the second substrate 32 are coupled in common to the wiring substrate 80, achieving a cost reduction.

Among the three electro-optical devices 1(R), 1(G), and 1(B), the electro-optical devices 1(G) and 1(B) each have the configuration illustrated in FIG. 7. On the other hand, even though the electro-optical device 1(R) has a basic configuration identical to a basic configuration of the electro-optical device 1(B), a bending direction of the fourth extended portion 324 is opposite to a bending direction of the electro-optical device 1(B). Therefore, the first substrates 31 of the electro-optical devices 1(R) and 1(B) both lying on the front side (the side b1 in the b axis direction) arranged with the projection optical system 206 are linearly arranged. That is, the fourth extended portions 324 of the second substrates 32 of the electro-optical devices 1(R) and 1(B) bend toward an opposite side to the projection optical system 206. Therefore, on each of the electro-optical devices 1(R) and 1(B), in the first substrate 31 and the second substrate 32, a whole of the substrates including the first extended portion 313, the second extended portion 314, the first terminal region forming portion 318, the third extended portion 323, the fourth extended portion 324, and the second terminal region forming portion 328 described with reference to FIG. 7 does not protrude from a virtual surface F including the emission surface 225 toward the projection optical system 206. Therefore, a space for arranging actuators, for example, each configured to perform focusing-driving in the projection optical system 206, and a movable region for the projection optical system 206, for example, can be secured around the virtual surface F.

### Exemplary Embodiment 2

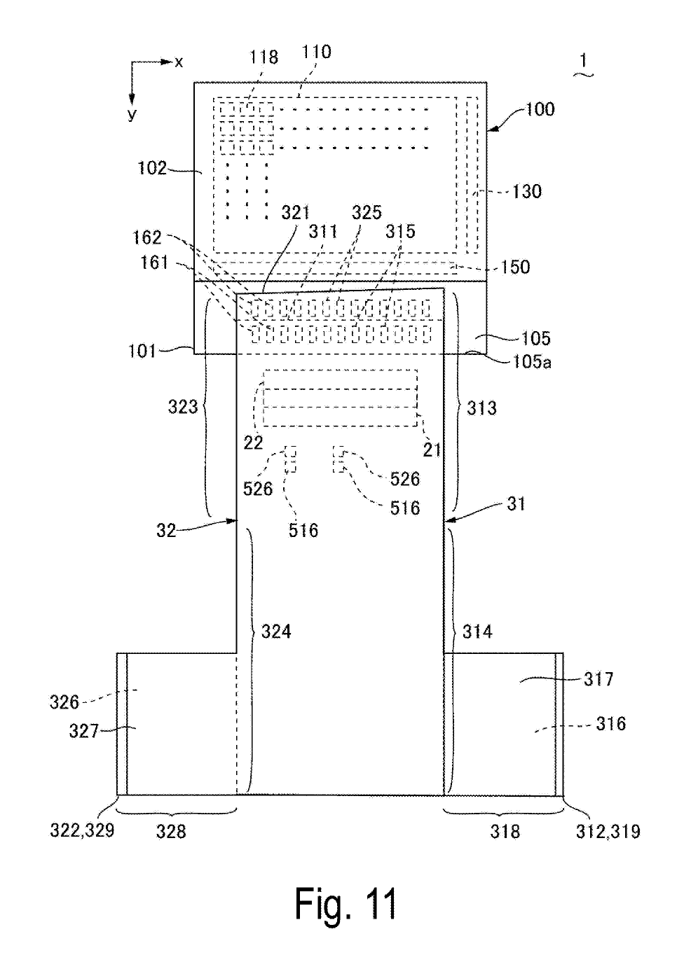

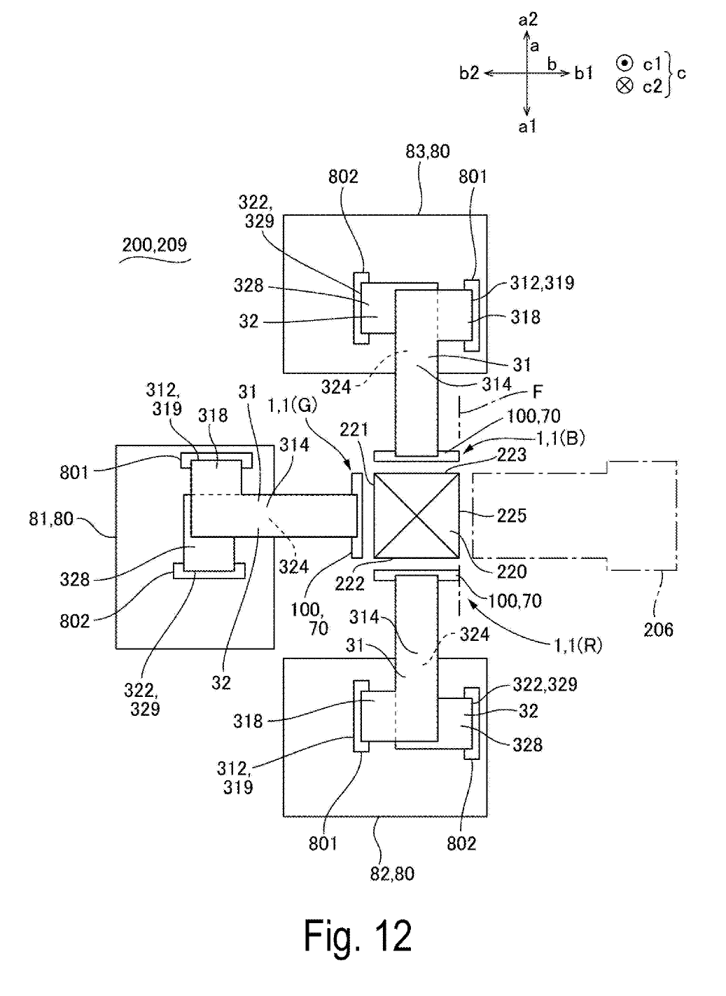

FIG. 11 is an explanatory view schematically illustrating a planar configuration of an electro-optical device 1 according to Exemplary Embodiment 2 of the invention. FIG. 12 is an explanatory view schematically illustrating the electro-optical devices 1 illustrated in FIG. 11 arranged around the cross dichroic prism 220. Note that a basic configuration of the electro-optical device 1 according to Exemplary Embodiment 2 and basic configurations of electro-optical devices 1 according to Exemplary Embodiments 3, 4, and 5 described below are the same as the basic configuration of the electro-optical device 1 according to Exemplary Embodiment 1. Hence, corresponding reference signs are given to corresponding components, and corresponding descriptions are omitted.

As illustrated in FIG. 11, the electro-optical device 1 according to the exemplary embodiment includes, similar to Exemplary Embodiment 1, the first substrate 31 having flexibility and including the first end 311 coupled to an end of the element substrate 101 of the electro-optical panel 100, and the second substrate 32 overlapped with the first substrate 31 in the thickness direction and having flexibility, and moreover including the third end 321 coupled to the end of the element substrate 101 of the electro-optical panel 100. The first substrate 31 and the second substrate 32 extend from the electro-optical panel 100 in the y axis direction.

On the first substrate 31, the first terminal region 319 arranged with a plurality of terminals (not illustrated) is provided on the second end 312 lying opposite to the first end 311. On the second substrate 32, the second terminal region 329 arranged with a plurality of terminals (not illustrated) is provided on the fourth end 322 lying opposite to the third end 321. The first terminal region 319 and the second terminal region 329 are electrically coupled with a higher control circuit, for example.

In the exemplary embodiment, as described below, when the first substrate 31 and the second substrate 32 are developed on the same plane (on an x-y plane), the first terminal region 319 and the second terminal region 329 are located at positions different from each other on the plane described above, and do not overlap with each other in the thickness direction.

More specifically, the first substrate 31 includes the first extended portion 313 extending in the y axis direction to an intermediate position from the first end 311 toward the second end 312, the first terminal region forming portion 318 including the second end 312 and formed with the first terminal region 319, and the second extended portion 314 extending in the y axis direction from the first extended portion 313 to the first terminal region forming portion 318. The first terminal region forming portion 318 protrudes in the x axis direction from the second extended portion 314. The first end 312 (the first terminal region 319) of the first substrate 31 extends in the x axis direction orthogonal to the extending direction of the second extended portion 314.

The second substrate 32 includes the third extended portion 323 extending in the y axis direction to an intermediate position from the third end 321 toward the fourth end 322 to overlap with the first extended portion 313 in the thickness direction (the z axis direction), the second terminal region forming portion 328 including the fourth end 322 and formed with the second terminal region 329, and the fourth extended portion 324 extending from the third extended portion 313 to the second terminal region forming portion 328. The fourth extended portion 324 extends from the third extended portion 324 to the second terminal region forming portion 328 to overlap with the second extended portion 314 in the thickness direction. The second terminal region forming portion 328 protrudes from the fourth extended portion 324 in the x axis direction toward an opposite side to the first terminal region forming portion 318. Therefore, the second end 312 (the first terminal region 319) of the first substrate 31 and the fourth end 322 (the second terminal region 329) of the second substrate 32 respectively extend in the extending direction (y axis direction) of the first extended portion 313 to positions away from each other in the x axis direction.

On the surface 316 of the first substrate 31, the first extended portion 313 is mounted with the electronic components 516, such as the first driving IC 21 and a capacitor. On the surface 326 of the second substrate 32, the third extended portion 323 is mounted with the electronic components 526, such as the second driving IC 22 and a capacitor.

In the exemplary embodiment, a distance from the first end 311 to the first driving IC 21 on the first substrate 31 and a distance from the third end 321 to the second driving IC 22 on the second substrate 32 are identical to each other. A distance from the electro-optical panel 100 to the second end 312 of the first substrate 31 and a distance from the electro-optical panel 100 to the fourth end 322 of the second substrate 32 are identical to each other. However, such an aspect may be adopted that the fourth end 322 of the second substrate 32 is closer to the electro-optical panel 100 than the second end 312 of the first substrate 31 by a gap in the y axis direction between the first terminals 161 and the second terminals 162. According to the aspect, a length from the first end 311 to the second end 312 on the first substrate 31 and a length from the third end 321 to the fourth end 322 on the second substrate 32 are identical to each other. Therefore, a wiring distance from the second end 312 to the first driving IC 21 and a wiring distance from the fourth end 322 to the second driving IC 22 can be made identical to each other. Also, a wiring distance from the first driving IC 21 to the first end 311 and a wiring distance from the second driving IC 22 to the third end 321 can be made identical to each other.

As described above, in the electro-optical device 1 according to the exemplary embodiment, the first substrate 31 and the second substrate 32 overlapped with each other in the thickness direction are coupled to the electro-optical panel 100. The first extended portion 313 of the first substrate 31 and the third extended portion 323 of the second substrate 32 overlapped with each other linearly extend. Therefore, the first substrate 31 and the second substrate 32 can be arranged within a narrower space around the electro-optical panel 100.

Even in this case, the second extended portion 314 of the first substrate 31 and the fourth extended portion 324 of the second substrate 32 separated away from each other in the x axis direction extend. Therefore, the first terminal region 319 and the second terminal region 329 do not overlap with each other in the thickness direction. Therefore, the other end (the second end 312 and the first terminal region 319) of the first substrate 31 and the other end (the fourth end 322 and the second terminal region 329) of the second substrate 32 can be coupled in common to a wiring substrate, achieving an efficient coupling operation, for example, similar to Exemplary Embodiment 1.

As illustrated in FIG. 12, when mounting the electro-optical device 1 according to the exemplary embodiment onto the projection-type display device 200 (electronic device), similar to Exemplary Embodiment 1, while the first substrate 31 and the second substrate 32 respectively bend in a direction identical to the thickness direction at intermediate positions in the extending direction, the first terminal region 319 and the second terminal region 329 are coupled in common to the wiring substrate 80. More specifically, in each of the three electro-optical devices 1(R), 1(G), and 1(B), the first substrate 31 and the second substrate 32 are respectively arranged to bend in the thickness direction toward the opposite side to the cross dichroic prism 220 at intermediate positions in the extending direction. The three electro-optical devices 1(R), 1(G), and 1(B) have configurations identical to each other, and are arranged in a rotational symmetry manner about the cross dichroic prism 220. In this state, the first extended portion 313, the second extended portion 314, the third extended portion 323, and the fourth extended portion 324 described with reference to FIG. 11 do not protrude from the virtual surface F including the emission surface 225 toward the projection optical system 206. Therefore, a space for arranging actuators, for example, each configured to perform focusing-driving in the projection optical system 206, and a movable region for the projection optical system 206, for example, can be secured around the virtual surface F. The first terminal region 319 and the second terminal region 329 are coupled in common to the wiring substrate 80 (the first wiring substrate 81, the second wiring substrate 82, and the third wiring substrate 83) arranged in parallel to incident light emitted to each of the electro-optical devices 1(R), 1(G), and 1(B). Therefore, in each of the electro-optical devices 1(R), 1(G), and 1(B), without hindered by the tip sides of the first substrate 31 and the second substrate 32 and the wiring substrate 80, an optical path of incident light to each of the electro-optical devices 1(R), 1(G), and 1(B) can be secured.

Even in the exemplary embodiment, similar to Exemplary Embodiment 1, the first terminal region 319 and the second terminal region 329 respectively serve as plugs for a board-to-board connector, for example. Therefore, the first wiring substrate 81, the second wiring substrate 82, and the third wiring substrate 83 are each formed with the socket 801 of the board-to-board connector to be inserted with the first terminal region 319, and the socket 802 of the board-to-board connector to be inserted with the second terminal region 329. In the exemplary embodiment, the sockets 801 and 802 are arranged in parallel to each other. Therefore, the first terminal region 319 and the second terminal region 329 can be respectively easily inserted into the sockets 801 and 802. In each of the three electro-optical devices 1(R), 1(G), and 1(B), the first terminal region 319 of the first substrate 31 and the second terminal region 329 of the second substrate 32 are coupled in common to the wiring substrate 80, achieving a cost reduction.

In the exemplary embodiment, the first terminal region forming portion 318 and the second terminal region forming portion 328 respectively bend at right angles to be opposite to each other from the second extended portion 314 and the fourth extended portion 324. However, such an aspect may be adopted that the first terminal region forming portion 318 and the second terminal region forming portion 328 respectively bend diagonally in directions opposite to each other from the second extended portion 314 and the fourth extended portion 324, and then extend in the y axis direction. In this case, similar to Exemplary Embodiment 1, such an aspect may be adopted that the second end 312 (the first terminal region 319) of the first substrate 31 extends in the x axis direction orthogonal to the extending direction of the first extended portion 313 to a position away in the x axis direction orthogonal to the extending direction of the first extended portion 313 from the fourth end 322 (the second terminal region 329) of the second substrate 32. In the exemplary embodiment, the first terminal region forming portion 318 and the second terminal region forming portion 328 respectively bend at right angles to be opposite to each other from the second extended portion 314 and the fourth extended portion 324. However, such an aspect may be adopted that only the first terminal region forming portion 318 protrudes from the second extended portion 314, for example.

### Exemplary Embodiment 3

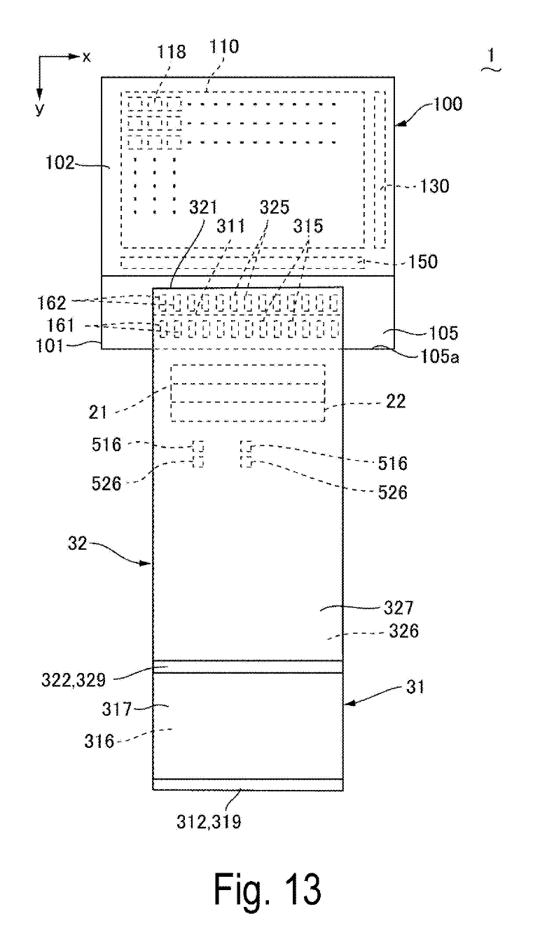

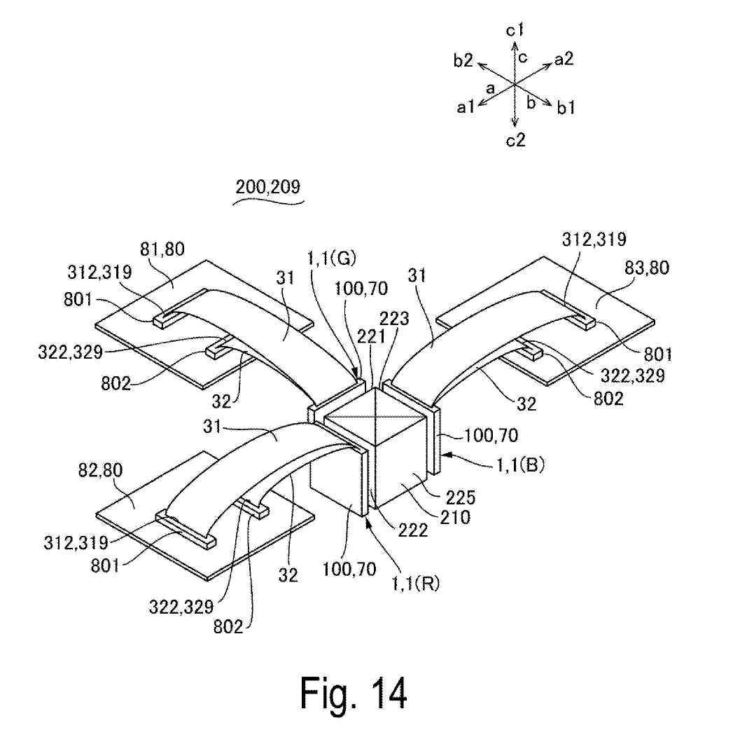

FIG. 13 is an explanatory view schematically illustrating a planar configuration of an electro-optical device 1 according to Exemplary Embodiment 3 of the invention. FIG. 14 is an explanatory view schematically illustrating the electro-optical devices 1 illustrated in FIG. 13 arranged around the cross dichroic prism 220.

As illustrated in FIG. 13, the electro-optical device 1 according to the exemplary embodiment includes, similar to Exemplary Embodiment 1, the first substrate 31 having flexibility and including the first end 311 coupled to the end of the element substrate 101 of the electro-optical panel 100, and the second substrate 32 overlapped with the first substrate 31 in the thickness direction and having flexibility, and moreover including the third end 321 coupled to the end of the element substrate 101 of the electro-optical panel 100. The first substrate 31 and the second substrate 32 extend from the electro-optical panel 100 in the y axis direction.

The first substrate 31 and the second substrate 32 respectively linearly extend in a single direction to lengths different from each other. Therefore, the second end 312 (the first terminal region 319) of the first substrate 31 and the fourth end 322 (the second terminal region 329) of the second substrate 32 are located at positions different from each other in the in-plane direction of the first substrate 31 and the second substrate 32, and do not overlap with each other in the thickness direction. In the exemplary embodiment, the first substrate 31 is longer than the second substrate 32. Therefore, the second end 312 (the first terminal region 319) of the first substrate 31 and the second substrate 32 do not overlap with each other, but the fourth end 322 (the second terminal region 329) of the second substrate 32 overlaps with an intermediate position, in the extending direction, of the first substrate 31.

As illustrated in FIG. 14, when mounting the electro-optical device 1 according to the exemplary embodiment onto the projection-type display device 200 (electronic device), similar to Exemplary Embodiment 1, while the first substrate 31 and the second substrate 32 respectively bend in a direction identical to the thickness direction at intermediate positions in the extending direction, the first terminal region 319 and the second terminal region 329 are coupled to the wiring substrate 80. More specifically, in each of the three electro-optical devices 1(R), 1(G), and 1(B), the first substrate 31 and the second substrate 32 are respectively arranged to bend in the thickness direction toward the opposite side to the cross dichroic prism 220 at intermediate positions in the extending direction. Therefore, the first terminal region 319 and the second terminal region 329 are coupled in common to the wiring substrate 80 (the first wiring substrate 81, the second wiring substrate 82, and the third wiring substrate 83) arranged in parallel to incident light to each of the electro-optical devices 1(R), 1(G), and 1(B). Therefore, in each of the electro-optical devices 1(R), 1(G), and 1(B), without hindered by the tip sides of the first substrate 31 and the second substrate 32 and the wiring substrate 80, an optical path of incident light to each of the electro-optical devices 1(R), 1(G), and 1(B) can be secured. The three electro-optical devices 1(R), 1(G), and 1(B) respectively have configurations identical to each other, and are arranged in a rotational symmetry manner about the cross dichroic prism 220.

Even in the exemplary embodiment, similar to Exemplary Embodiment 1, the first terminal region 319 and the second terminal region 329 respectively serve as plugs for a board-to-board connector, for example. Therefore, the first wiring substrate 81, the second wiring substrate 82, and the third wiring substrate 83 are each formed with the socket 801 of the board-to-board connector to be inserted with the first terminal region 319, and the socket 802 of the board-to-board connector to be inserted with the second terminal region 329. In the exemplary embodiment, the sockets 801 and 802 are arranged in parallel to each other. The first terminal region 319 and the second terminal region 329 do not overlap with each other in the thickness direction. Therefore, after the other end (the second end 312 and the first terminal region 319) of the first substrate 31 is coupled to the wiring substrate 80, when coupling the other end (the fourth end 322 and the second terminal region 329) of the second substrate 32 to the wiring substrate 80, the first substrate 31 does not become an obstruction, achieving an efficient coupling operation. In each of the electro-optical devices 1(R) and 1(B), the first substrate 31 and the second substrate 32 do not protrude from the virtual surface including the emission surface 225 toward the side b1 (a side of the projection optical system 206 illustrated in FIG. 1) in the b axis direction. Therefore, a space for arranging actuators, for example, each configured to perform focusing-driving in the projection optical system 206, and a movable region for the projection optical system 206, for example, can be secured around the cross dichroic prism 220.

### Exemplary Embodiment 4

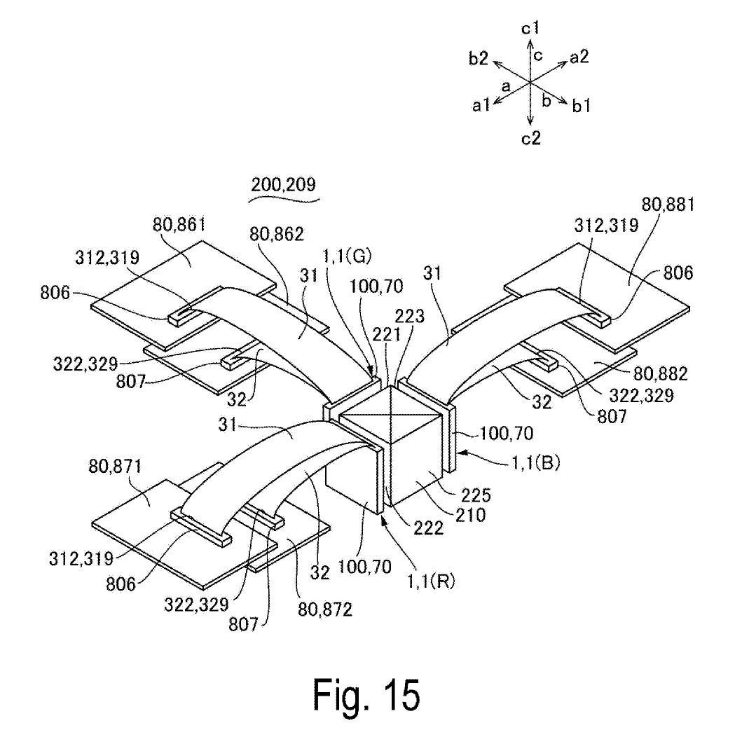

FIG. 15 is an explanatory view schematically illustrating electro-optical devices 1 arranged around the cross dichroic prism 220 in a projection-type display device 200 (electronic device), according to Exemplary Embodiment 4 of the invention. In the exemplary embodiment, the electro-optical device 1 is similar to the electro-optical device 1 according to Exemplary Embodiment 3 described with reference to FIG. 13, and the first substrate 31 and the second substrate 32 respectively linearly extend in a single direction to lengths different from each other. In the exemplary embodiment, the first substrate 31 is longer than the second substrate 32. Therefore, the second end 312 (the first terminal region 319) of the first substrate 31 and the second substrate 32 do not overlap with each other, but the fourth end 322 (the second terminal region 329) of the second substrate 32 overlaps with an intermediate position, in the extending direction, of the first substrate 31.

As illustrated in FIG. 15, when mounting the electro-optical device 1 according to the exemplary embodiment onto the projection-type display device 200 (electronic device), similar to Exemplary Embodiment 3, while the first substrate 31 and the second substrate 32 respectively bend in a direction identical to the thickness direction at intermediate positions in the extending direction, the first terminal region 319 and the second terminal region 329 are coupled to the wiring substrate 80. More specifically, in each of the three electro-optical devices 1(R), 1(G), and 1(B), the first substrate 31 and the second substrate 32 are respectively arranged to bend in the thickness direction toward the opposite side to the cross dichroic prism 220 at intermediate positions in the extending direction, and the first terminal region 319 and the second terminal region 329 are coupled to the wiring substrate 80.

In each of the three electro-optical devices 1(R), 1(G), and 1(B), the first terminal region 319 is away from the cross dichroic prism 220 farther than the second terminal region 329. Therefore, in the electro-optical device 1(G), the first terminal region 319 of the first substrate 31 is coupled to a socket 806 of a wiring substrate 861, while the second terminal region 329 is coupled to a socket 807 of another wiring substrate 862 partially overlapping with the wiring substrate 861. In the electro-optical device 1(R), the first terminal region 319 of the first substrate 31 is coupled to a socket 806 of a wiring substrate 871, while the second terminal region 329 is coupled to a socket 807 of another wiring substrate 872 overlapping with the wiring substrate 871. In the electro-optical device 1(B), the first terminal region 319 of the first substrate 31 is coupled to a socket 806 of the wiring substrate 881, while the second terminal region 329 is coupled to a socket 807 of another wiring substrate 882 overlapping with the wiring substrate 881.

In the exemplary embodiment, as described above, the first substrate 31 and the second substrate 32 overlapping with each other extend in a single direction, but the first terminal region 319 and the second terminal region 329 do not overlap with each other in the thickness direction. Therefore, after the second terminal region 329 is coupled to the wiring substrate 882, when coupling the first terminal region 319 to the wiring substrate 881, the second substrate 32 does not become an obstruction, achieving an easy coupling operation. Even in the exemplary embodiment, similar to Exemplary Embodiment 3, in each of the electro-optical devices 1(R) and 1(B), the first substrate 31 and the second substrate 32 do not protrude from the virtual surface including the emission surface 225 toward the side b1 (a side of the projection optical system 206 illustrated in FIG. 1) in the b axis direction. Therefore, a space for arranging actuators, for example, each configured to perform focusing-driving in the projection optical system 206, and a movable region for the projection optical system 206, for example, can be secured around the cross dichroic prism 220.

### Exemplary Embodiment 5

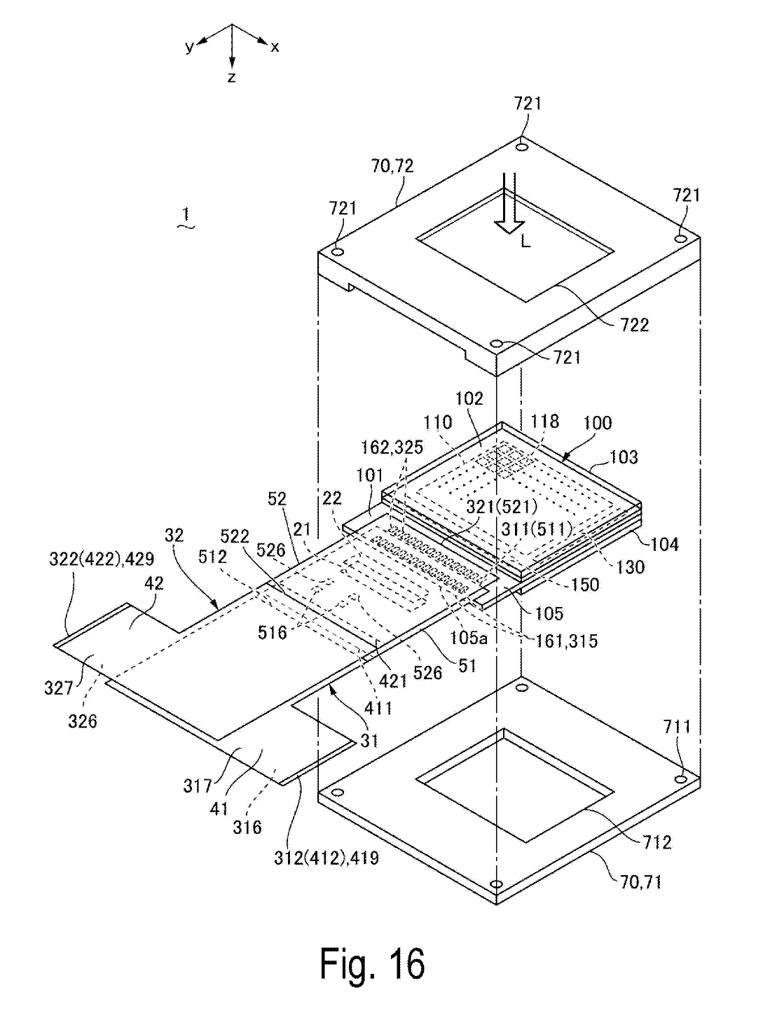

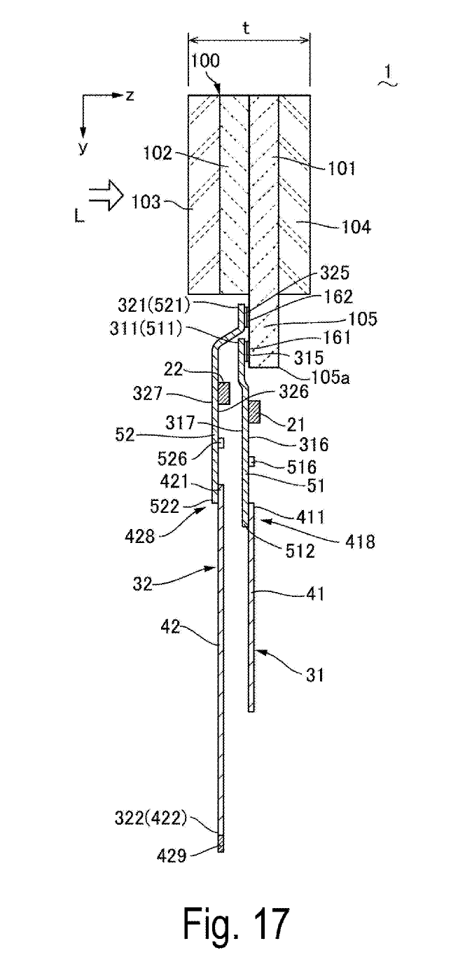

FIG. 16 is an exploded perspective view of an electro-optical device 1 according to Exemplary Embodiment 5 of the invention. FIG. 17 is an explanatory view illustrating a cross-sectional configuration of the electro-optical device 1 illustrated in FIG. 16. As illustrated in FIG. 16, the electro-optical device 1 according to the exemplary embodiment also includes, similar to Exemplary Embodiment 2, the first substrate 31 having flexibility and including the first end 311 coupled to the element substrate 101 of the electro-optical panel 100, and the second substrate 32 overlapping with the first substrate 31 in the thickness direction and having flexibility, and moreover including the third end 321 coupled to the element substrate 101 of the electro-optical panel 100. The first substrate 31 and the second substrate 32 extend from the electro-optical panel 100 in the y axis direction. On the first substrate 31, the first terminal region 319 arranged with a plurality of terminals (not illustrated) is provided on the second end 312 lying opposite to the first end 311. On the second substrate 32, the second terminal region 329 arranged with a plurality of terminals (not illustrated) is provided on the fourth end 322 lying opposite to the third end 321.

In the electro-optical device 1 configured as described above, the first substrate 31 includes a third substrate 51 mounted with the first driving IC 21 on a flexible substrate linearly extending from an end 511 coupled to the electro-optical panel 100, and a fourth substrate 41 having flexibility and including an end 411 coupled to another end 512 of the third substrate 51. Another end 412 of the fourth substrate 41 is provided with the first terminal region 319. The third substrate 51 configures the first extended portion 313 described with reference to FIG. 11. The fourth substrate 41 configures the second extended portion 314 and the first terminal region forming portion 318 described with reference to FIG. 11.

The second substrate 32 includes, similar to the first substrate 31, a fifth substrate 52 mounted with the second driving IC 22 on a flexible substrate linearly extending from an end 521 coupled to the electro-optical panel 100, and a sixth substrate 42 having flexibility and including an end 421 coupled to another end 522 of the fifth substrate 52. Another end 422 of the sixth substrate 42 is provided with the second terminal region 329. The fifth substrate 52 configures the third extended portion 323 described with reference to FIG. 11. The sixth substrate 42 configures the fourth extended portion 324 and the second terminal region forming portion 328 described with reference to FIG. 11.

According to the aspect, expensive chip-on-film (COF) substrates (the third substrate 51 and the fifth substrate 52) can be only partially used for the first substrate 31 and the second substrate 32, while cost-effective extension substrates (the fourth substrate 41 and the sixth substrate 42) can be used for the first substrate 31 and the second substrate 32 to achieve appropriate lengths. Therefore, a cost reduction can be achieved.

The third substrate 51 and the fifth substrate 52 are identical in shape and length, for example, and are respectively formed of COF substrates with identical specifications. Therefore, a cost reduction can be achieved.

In the aspect of the electro-optical device 1 according to Exemplary Embodiment 2, the first substrate 31 and the second substrate 32 are each formed of a COF substrate and an extension substrate coupled to each other. The aspect may be applied to the electro-optical devices 1 according to Exemplary Embodiments 1, 3, and 4.

### Other Exemplary Embodiments

In Exemplary Embodiments described above, as for the two substrates coupled to and overlap with the electro-optical panel 100, a lower one (adjacent to the electro-optical panel 100) of the substrates is specified to the “second substrate”, while an upper one (away from the electro-optical panel 100) of the substrates is specified to the “first substrate”. However, the lower one (adjacent to the electro-optical panel 100) of the substrates may be specified to the “first substrate”, while the upper one (away from the electro-optical panel 100) of the substrates may be specified to the “second substrate”.

In Exemplary Embodiments 1 and 2 described above, the first terminal region 319 and the second terminal region 329 are coupled in common to the wiring substrate 80. However, even in Exemplary Embodiments 1 and 2 described above, similar to Exemplary Embodiment 4, the first terminal region 319 and the second terminal region 329 may be respectively coupled to other wiring substrates 80 different from each other.

In each of Exemplary Embodiments described above, the number of the substrates coupled to the electro-optical panel 100 is two. However, the invention may be applied when a number of substrates is three or more.

In each of Exemplary Embodiments described above, the first terminal region 319 and the second terminal region 329 are coupled to the wiring substrate 80 via connectors. However, the invention may be applied when the first terminal region 319 and the second terminal region 329 are coupled to the wiring substrate 80 through soldering or with an anisotropic conductive film.

In each of Exemplary Embodiments described above, the electro-optical device 1 is equipped with the transmission type electro-optical panel 100. However, the invention may be applied when the electro-optical device 1 is equipped with a reflection type electro-optical panel 100.

In each of Exemplary Embodiments described above, the electro-optical panel 100 is a liquid crystal panel. However, the invention may be applied when the electro-optical panel 100 is an organic electro-luminescence display panel, a plasma display panel, a field emission display (FED) panel, a surface-conduction electron-emitter display (SED) panel, a light emitting diode (LED) display panel, or an electrophoresis display panel, for example.

The projection-type display device 200 described above may be configured to use, as a light source unit, an LED light source configured to emit light in various colors, and the like to supply light in various colors emitted from the LED light source to another liquid crystal device.

In each of Exemplary Embodiments described above, the projection-type display device 200 is used as an electronic device equipped with the electro-optical device 1 applied with the invention. However, the invention may be applied to electro-optical devices 1 used in electronic devices including projection type head-up displays (HUDs), direct-view type head-mounted displays (HMDs), personal computers, digital still cameras, and liquid crystal televisions, for example.

The entire disclosure of Japanese Patent Application No. 2017-247351, filed Dec. 25, 2017 is expressly incorporated by reference herein.

What is claimed is:

1. An electro-optical device comprising:
an electro-optical panel;
a first substrate having flexibility, the first substrate including:
a first end coupled to the electro-optical panel; and
a second end disposed opposite to the first end, the second end being provided with a first terminal region arranged with a plurality of terminals; and
a second substrate having flexibility, the second substrate including:
a third end coupled to the electro-optical panel; and
a fourth end disposed opposite to the third end, the fourth end being provided with a second terminal region arranged with a plurality of terminals,
wherein,
when the first substrate and the second substrate are developed on a same plane, the first substrate and the second substrate partially overlap with each other on the plane, and
the first terminal region and the second terminal region are located at positions different from each other on the plane.

2. The electro-optical device according to claim 1, wherein, when the first substrate and the second substrate are developed on the same plane,
the first substrate includes:
a first extended portion extending to an intermediate position from the first end toward the second end;
a first terminal region forming portion including the second end, the first terminal region forming portion being formed with the first terminal region; and
a second extended portion extending from the first extended portion to the first terminal region forming portion, and
the second substrate includes:
a third extended portion extending to an intermediate position from the third end toward the fourth end to overlap with the first extended portion in the thickness direction;
a second terminal region forming portion including the fourth end, the second terminal region forming portion being formed with the second terminal region; and
a fourth extended portion bending in a direction intersecting with an extending direction of the third extended portion and extending from the third extended portion to the second terminal region forming portion to disallow the first terminal region forming portion and the second terminal region forming portion to overlap with each other in the thickness direction.

3. The electro-optical device according to claim 2, wherein, when the first substrate and the second substrate are developed on the same plane, the first extended portion and the second extended portion extend in a same direction.

4. The electro-optical device according to claim 3, wherein, when the first substrate and the second substrate are developed on the same plane, the first terminal region and the second terminal region respectively extend in a direction intersecting with an extending direction of the first extended portion.

5. The electro-optical device according to claim 1, wherein, when the first substrate and the second substrate are developed on the same plane,
the first substrate includes:
a first extended portion extending to an intermediate position from the first end toward the second end;
a first terminal region forming portion including the second end, the first terminal region forming portion being formed with the first terminal region; and
a second extended portion extending from the first extended portion to the first terminal region forming portion, and
the second substrate includes:
a third extended portion extending to an intermediate position from the third end toward the fourth end to overlap with the first extended portion in the thickness direction;
a second terminal region forming portion including the fourth end, the second terminal region forming portion being formed with the second terminal region; and
a fourth extended portion extending from the third extended portion to the second terminal region forming portion to overlap with the second extended portion in the thickness direction.

6. The electro-optical device according to claim 5, wherein the first terminal region and the second terminal region each extend in the extending direction of the first extended portion.

7. The electro-optical device according to claim 1, wherein the first substrate and the second substrate each extend in a same direction to lengths different from each other.

8. The electro-optical device according to claim 1, wherein the first extended portion and the third extended portion each are mounted with a driving integrated circuit (IC).

9. The electro-optical device according to claim 8, wherein
the first substrate includes:
a third substrate mounted with the driving IC on a flexible substrate extending from an end coupled to the electro-optical panel; and
a fourth substrate having flexibility, coupled to another end of the third substrate, and provided with the first terminal region, and
the second substrate includes:
a fifth substrate mounted with the driving IC on a flexible substrate extending from an end coupled to the electro-optical panel; and
a sixth substrate having flexibility, coupled to another end of the fifth substrate, and provided with the second terminal region.

10. The electro-optical device according to claim 9, wherein the third substrate and the fifth substrate are identical in shape and length.

11. An electronic device comprising the electro-optical device according to claim 1, wherein, in a state where the first substrate and the second substrate respectively bend in a direction identical to the thickness direction at intermediate positions in the extending direction, the first terminal region and the second terminal region are coupled to a wiring substrate.

12. The electronic device according to claim 11, wherein the first terminal region and the second terminal region are coupled in common to the wiring substrate.

13. A projection-type display device, equipped with a plurality of the electro-optical devices according to claim 1, the projection-type display device comprising:
a light source unit configured to emit light source light to be incident to each of the plurality of electro-optical devices;
a cross dichroic prism configured to synthesize light modulated by each of the plurality of electro-optical devices; and
a projection optical system configured to project imaging light emitted from an emission surface of the cross dichroic prism,
wherein the plurality of electro-optical devices include:
a first electro-optical device facing a first incident surface facing the emission surface of the cross dichroic prism;
a second electro-optical device facing a second incident surface lying between the emission surface and the first incident surface of the cross dichroic prism; and
a third electro-optical device facing a third incident surface facing the second incident surface of the cross dichroic prism, and,
in each of the first electro-optical device, the second electro-optical device, and the third electro-optical device, in a state where the first substrate and the second substrate each bend in the thickness direction toward an opposite side to the cross dichroic prism at intermediate positions in the extending direction, the first terminal region and the second terminal region are coupled to a wiring substrate.

14. The projection-type display device according to claim 13, wherein the first terminal region and the second terminal region are coupled in common to the wiring substrate.

15. A projection-type display device, equipped with a plurality of the electro-optical devices according to claim 2, the projection-type display device comprising:
a light source unit configured to emit light source light to be incident to each of the plurality of electro-optical devices;
a cross dichroic prism configured to synthesize light modulated by each of the plurality of electro-optical devices; and
a projection optical system configured to project imaging light emitted from an emission surface of the cross dichroic prism,
wherein the plurality of electro-optical devices include:
a first electro-optical device facing a first incident surface facing the emission surface of the cross dichroic prism;
a second electro-optical device facing a second incident surface lying between the emission surface and the first incident surface of the cross dichroic prism; and
a third electro-optical device facing a third incident surface facing the second incident surface of the cross dichroic prism,
wherein,
in each of the first electro-optical device, the second electro-optical device, and the third electro-optical device, in a state where the first substrate and the second substrate each bend in the thickness direction toward an opposite side to the cross dichroic prism at intermediate positions in the extending direction, the first terminal region and the second terminal region are coupled to a wiring substrate, and,
in each of the second electro-optical device and the third electro-optical device, the fourth extended portion bends in a direction to be away from the projection optical system.

16. The projection-type display device according to claim 13, wherein, in each of the second electro-optical device and the third electro-optical device, the first extended portion, the second extended portion, the third extended portion, and the fourth extended portion do not protrude from a virtual surface including the emission surface toward the projection optical system.
